(19) United States
(12) Patent Application Publication
(10) Pub. No.: US 2026/0324521 A1
(43) Pub. Date: Oct. 15, 2026

(54) SEMICONDUCTOR PACKAGE WITH BRIDGE CLIP

(71) Applicant: TEXAS INSTRUMENTS INCORPORATED, Dallas, TX (US)

(72) Inventors: John Carlo C. MOLINA, Limay (PH); Jason B. COLTE, La Trinidad (PH); Jonathan Andrew MONTOYA, Dallas, TX (US); Charmaine Grace FACAL, Olongapo City (PH)

(21) Appl. No.: 19/402,443

(22) Filed: Nov. 26, 2025

Related U.S. Application Data
(60) Provisional application No. 63/787,408, filed on Apr. 11, 2025.

(51) Int. Cl. H10W 90/00; H10W 70/04; H10W 74/10

(52) U.S. Cl. CPC H10W 90/701; H10W 70/048; H10W 90/00; H10W 74/114

(57) ABSTRACT

In examples, a semiconductor package includes a substrate having one or more electrical contacts, a semiconductor die coupled to the substrate, and a metal member having a top segment and first and second legs. The first leg extends from a first side of the top segment to the one or more electrical contacts. The second leg extends from a second side of the top segment to the one or more electrical contacts. The package includes a mold compound having a top surface and a bottom surface opposite the top surface. The bottom surface contacts the substrate. The top segment is exposed through the top surface. The package includes a passive electrical component having an electrical contact coupled to the top segment.

### CROSS-REFERENCE TO RELATED APPLICATIONS

The present application claims priority to U.S. Provisional Patent Application No. 63/787,408, which was filed on April 11, 2025, is titled “CLIP FOR EXPOSED INDUCTORS,” and is hereby incorporated herein by reference in its entirety.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such integrated circuits on a wafer is called fabrication. After wafer fabrication, the wafer is cut into multiple pieces, called semiconductor dies, with each die containing one or more of the integrated circuits. The cutting, or sawing, of the wafer into individual dies is called singulation. An individual die may then be attached to a die attach pad and to conductive terminals. The die attach pad and the conductive terminals are portions of a lead frame. The resulting structure is subsequently covered with a mold compound to produce a package.

### SUMMARY

In examples, a semiconductor package includes a substrate having one or more electrical contacts, a semiconductor die coupled to the substrate, and a metal member having a top segment and first and second legs. The first leg extends from a first side of the top segment to the one or more electrical contacts. The second leg extends from a second side of the top segment to the one or more electrical contacts. The package includes a mold compound having a top surface and a bottom surface opposite the top surface. The bottom surface contacts the substrate. The top segment is exposed through the top surface. The package includes a passive electrical component having an electrical contact coupled to the top segment.

In examples, a method for manufacturing a semiconductor package includes coupling a semiconductor die to a first substrate, the first substrate consecutive with a second substrate in a substrate strip; coupling first and second legs of a metal member to the first substrate and third and fourth legs of the metal member to the second substrate, the metal member having a top segment from which the first, second, third, and fourth legs extend, the top segment having portions defining an opening having a first oval portion, a second oval portion, and a rectangular portion

between the first and second oval portions; applying a mold compound to the substrate strip, the semiconductor die, and the metal member; coupling a passive electrical component to the top segment; and sawing through the portions of the metal member defining the opening.

### BRIEF DESCRIPTION OF DRAWINGS

FIGS. 1A, 1B, 1C, 1D, 1E, and 1F are various top-down, profile, bottom-up, and three-dimensional (3D) views of a semiconductor package with a bridge clip, in accordance with various examples.

FIGS. 1G, 1H, and 1I are various 3D views of a semiconductor package with a bridge clip, in accordance with various examples.

FIG. 2 is a flow diagram of a method for manufacturing a semiconductor package with a bridge clip, in accordance with various examples.

FIGS. 3A, 3B, 3C, and 3D are a process flow for manufacturing a semiconductor package with a bridge clip, in accordance with various examples.

FIGS. 4A, 4B, 4C, and 4D are elevation, profile, top-down, and 3D views, respectively, of an example bridge clip useful in a semiconductor package, in accordance with various examples.

FIGS. 5A, 5B, 5C, and 5D are elevation, profile, top-down, and 3D views, respectively, of an example bridge clip useful in a semiconductor package, in accordance with various examples.

FIGS. 6A, 6B, 6C, and 6D are elevation, profile, top-down, and 3D views, respectively, of an example bridge clip useful in a semiconductor package, in accordance with various examples.

FIGS. 7A, 7B, 7C, and 7D are elevation, profile, top-down, and 3D views, respectively, of an example bridge clip useful in a semiconductor package, in accordance with various examples.

FIG. 8 is a block diagram of an electronic device including a semiconductor package with a bridge clip, in accordance with various examples.

### DETAILED DESCRIPTION

Semiconductor packages often require external inductors to be attached after the molding process to achieve desired electrical performance characteristics. This post-molding attachment presents several technical challenges that affect both manufacturing efficiency and product reliability. One such challenge involves establishing reliable electrical connections between the exposed terminals of the inductor and the electrical contacts on the underlying substrate through the intervening mold compound material.

Conventional connector solutions for post-molding inductor attachment face limitations in mechanical stability during assembly operations. Individual copper clips or posts may be prone to toppling or shifting during the various handling steps of the manufacturing process, including stencil printing, component placement, and transfer to reflow operations. These mechanical instabilities can lead to the misalignment of connections and potential assembly defects that affect product yield and reliability.

Existing connector designs also present restrictions on design flexibility when accommodating different inductor sizes and terminal configurations. As power density requirements increase, there is a need to support a mix of terminal types from different inductor suppliers while maintaining adequate contact area for higher current applications. Insufficient contact area between the connector and inductor terminals can result in higher resistance losses and potential long-term reliability issues related to electromigration effects.

The challenge of achieving greater overlap between connector elements and inductor terminals without consuming additional package footprint area represents another limitation of conventional approaches. Traditional connector designs require larger package areas to accommodate the necessary contact surfaces, which conflicts with the industry trend toward higher power density and smaller form factors.

This description presents various examples of a multi-legged (i.e., four or more legs) bridge clip that mitigates these technical challenges by spanning across two adjacent semiconductor packages during the manufacturing process before singulation occurs. This bridging configuration provides enhanced mechanical stability during pick and place assembly operations by creating a wider, more stable structure with four or more legs that resists toppling and shifting during handling steps. The increased stability stems from the broader base of support that the bridge configuration provides compared to individual narrow connector elements. Such bridging across two adjacent semiconductor packages enables complex bridge clip geometries (e.g., two-legged clips) that would not be mechanically stable as standalone connectors. By coupling the bridge clip to adjacent units during assembly, the design may accommodate extended contact surfaces and protruding elements that provide improved electrical contact with inductor terminals. This approach allows for greater overlap between the connector and inductor terminals without requiring additional package footprint area, as the connector structure extends over the die area rather than consuming peripheral package space.

The bridge clip incorporates dumbbell-shaped openings that facilitate efficient singulation with low mechanical saw wear and tear while providing mold locking features. These openings include recessed portions that become filled with mold compound during the molding process, creating mechanical interlocking between the connector and the mold material. Non-recessed portions remain exposed through the side surfaces of the mold compound after singulation, providing visible evidence of the original bridge structure and maintaining electrical connectivity.

The design provides assembly robustness by reducing the likelihood of component displacement during the multiple handling steps involved in semiconductor package manufacturing. The enhanced stability during component placement and reflow operations may result in improved manufacturing yields and reduced assembly defects compared to individual connector approaches.

Design reusability across multiple product lines and package generations represents another technical advantage of the bridge clip approach. A single bridge clip design may accommodate different inductor sizes and terminal configurations, enabling the same connector structure to be used across various semiconductor package designs. This design portability reduces development time and manufacturing complexity while providing flexibility to accommodate varying inductor terminal types from different suppliers.

The bridge clip design may also support higher current applications by providing increased contact area between the connector and inductor terminals. The enhanced contact area reduces resistance losses and addresses potential electromigration concerns that may arise in high-current power applications. The ability to create larger contact surfaces without consuming additional package area contributes to improved power density characteristics in the final semiconductor package.

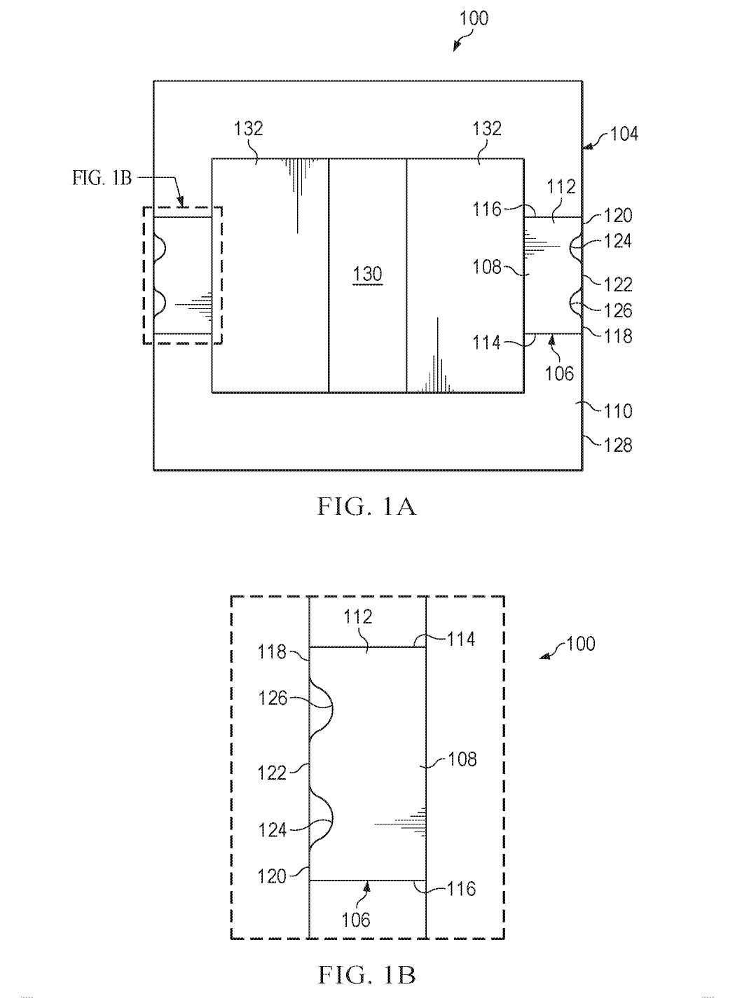

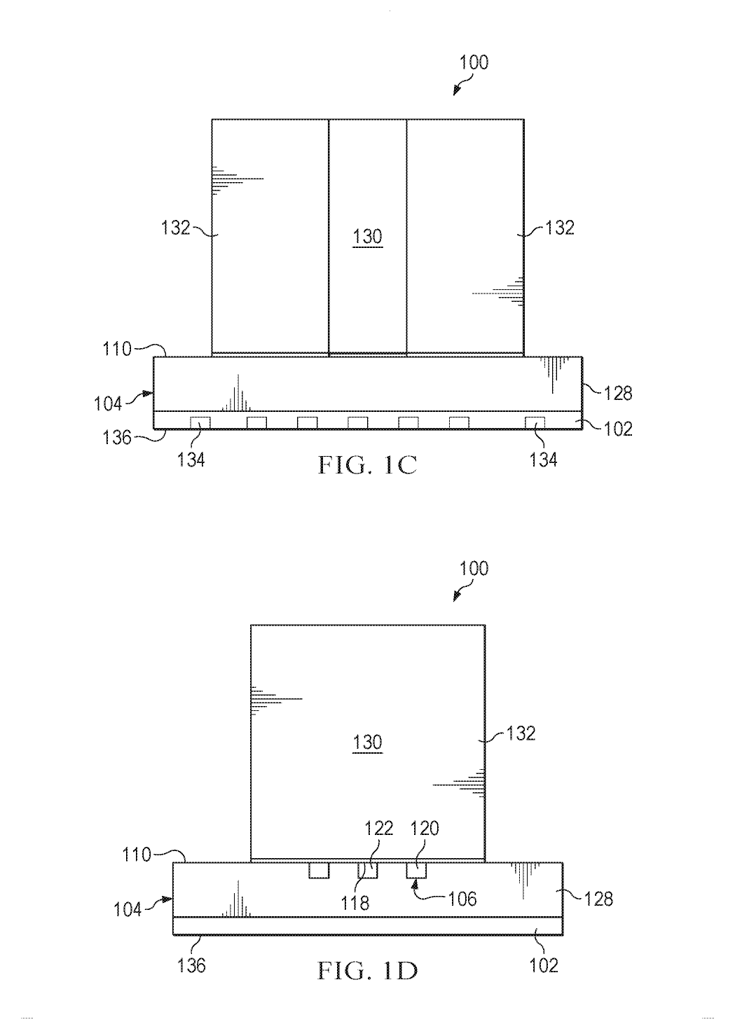

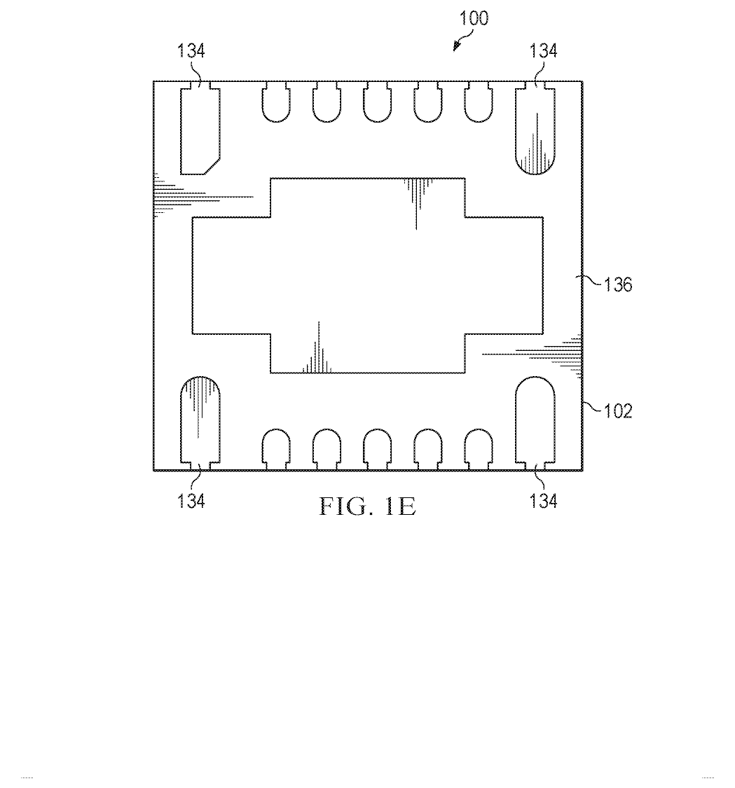

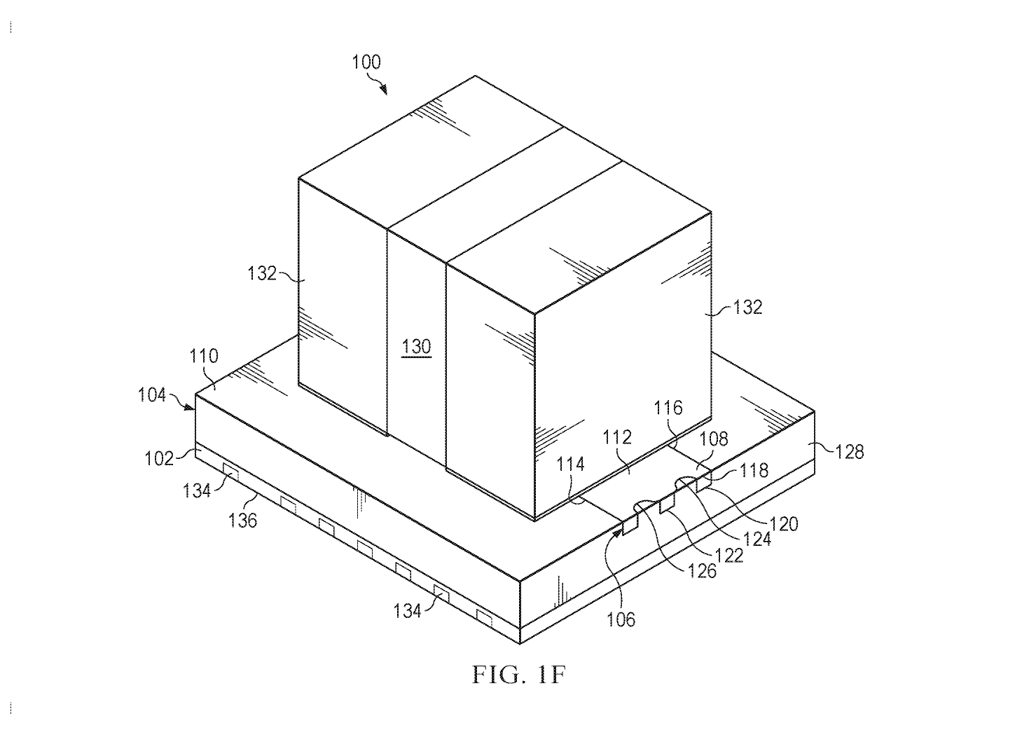

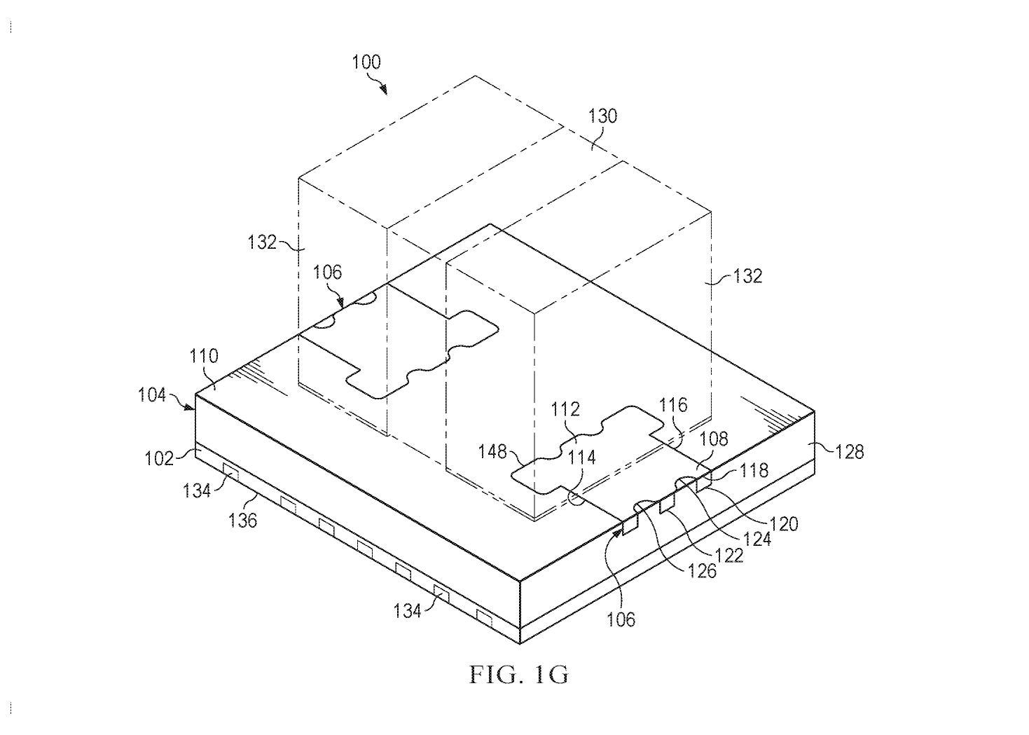

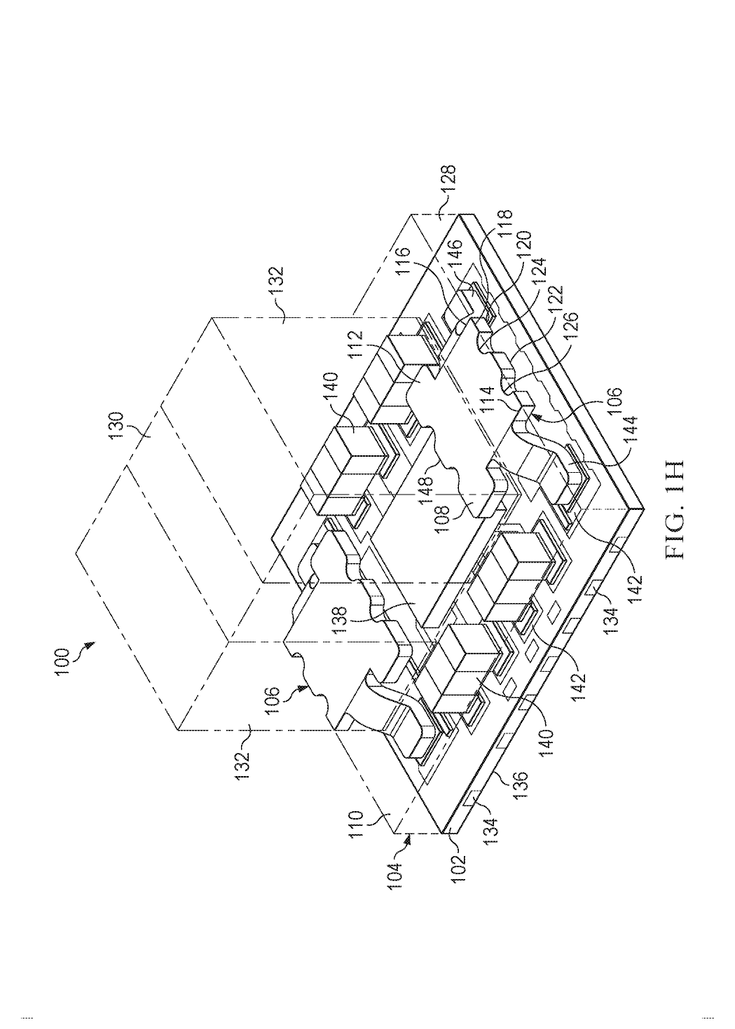

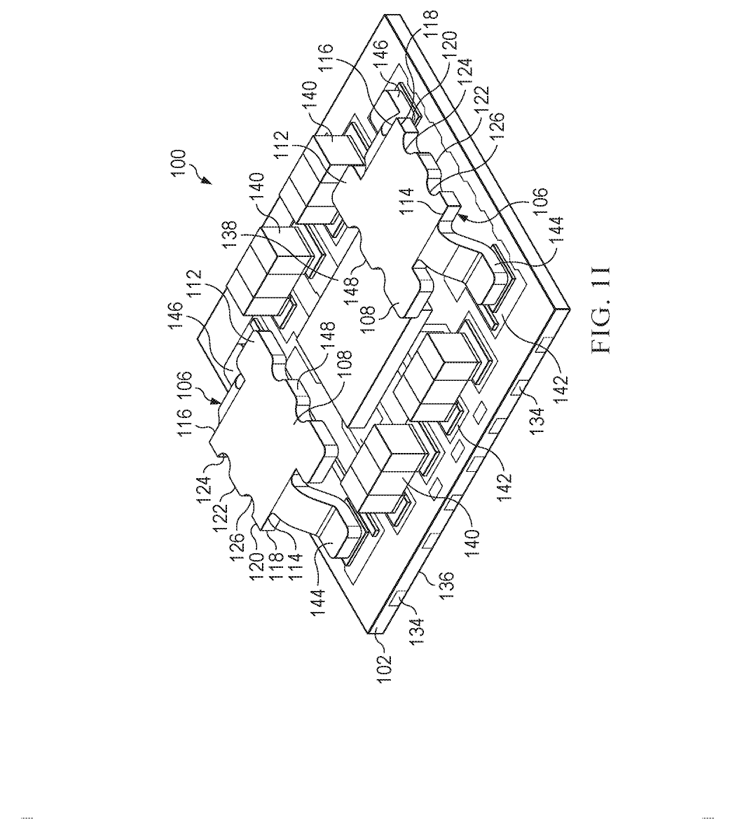

FIGS. 1A-1I present various top-down, profile, bottom-up, and 3D views of a semiconductor package 100 with a bridge clip, in accordance with various examples. Referring simultaneously to FIGS. 1A-1F, an example semiconductor package 100 includes a substrate 102 and a mold compound 104 contacting a top surface of the substrate 102. As described below with reference to FIGS. 1G-1I, the mold compound 104 encapsulates various components, such as a semiconductor die, passive components, electrical contacts, and so on. The semiconductor package 100 also includes a metal member 106, also referred to herein as a bridge clip. The mold compound

104 contacts some, but not all, portions of the metal member 106. In particular, the metal member 106 includes a top segment 112 having a top surface 108 that is exposed through a top surface 110 of the mold compound 104. In examples, the top surfaces 110 and 108 are approximately flush with each other.

The top segment 112 of the metal member 106 includes a first side 114, a second side 116, and a third side 118. The first side 114 and the second side 116 may be approximately parallel to each other. The third side 118 may be approximately orthogonal to the first side 114 and the second side 116. The metal member 106 includes legs (obscured from view by the mold compound 104 in FIGS. 1A-1G, but visible in FIGS. 1H and 1I and described below) that extend from the first side 114 and the second side 116, downward through the mold compound 104, to the substrate 102. The metal member 106 also includes non-recessed portions 120 and 122 and recessed portions 124 and 126 along the third side 118. The non-recessed portions 120 and 122 and the recessed portions 124 and 126 may be configured in an alternating pattern, such as with the recessed portion 124 in between the non-recessed portions 120 and 122, and with the non-recessed portion 122 in between the recessed portions 124 and 126. The third side 118 may include additional recessed and/or non-recessed portions. The mold compound 104 may fill the recessed portions 124 and 126, thereby forming a mechanical interlocking feature that promotes robust adhesion between the metal member 106 and the mold compound 104.

The mold compound 104 also includes a side surface 128. Portions of the metal member 106 are exposed through the side surface 128, for example, by being approximately flush with the side surface 128. For instance, the non-recessed portions 120 and 122 may be exposed through the side surface 128, and thus visible in the profile view of FIG. 1D. Conversely, the recessed portions 124 and 126 are not exposed through the side surface 128, and thus are not visible in the profile view of FIG. 1D. Although the recessed portions 124 and 126 are depicted as concave and rounded, other shapes for the recessed portions 124 and 126 are contemplated and included in the scope of this description, such as rectangular, diamond, etc.

The semiconductor package 100 includes a passive electrical component 130. The passive electrical component 130 is assumed herein to be an inductor, but the scope of this description encompasses any and all types of components that may be coupled to a semiconductor die of a package by dual terminals using surface mount technology. The passive electrical component 130 includes a terminal 132 that is coupled (e.g., soldered) to the top segment 112.

Because the passive electrical component 130 may include multiple such terminals 132, the semiconductor package 100 may include multiple instances of the metal member 106, with each metal member 106 coupled to a different terminal 132 of the passive electrical component 130.

The substrate 102 includes the top surface (obscured by the mold compound 104 in FIGS. 1A-1G) to which various components, such as the legs of the metal member 106, the semiconductor die, the passive components, etc. are coupled. The substrate 102 also includes side surfaces through which conductive terminals 134 (e.g., quad flat no lead (QFN)-style) are exposed for coupling to a printed circuit board. The substrate 102 also includes a bottom surface 136, on which the conductive terminals 134 are exposed. Other metal structures within the substrate 102 also may be exposed on the bottom surface 136, such as to establish electrical connections or to dissipate heat.

FIGS. 1G-1I provide various 3D views of structures that are otherwise obscured from views in FIGS. 1A-1F. In FIG. 1G, the passive electrical component 130 is made transparent to depict the connection between the terminals 132 and the top segments 112 of the metal members 106. As shown, each conductive terminal 132 has substantial overlap with the corresponding top segment 112 in the top-down view, thereby enabling superior electrical characteristics, such as improved current throughput, without enlarging the package footprint area.

FIG. 1H depicts the semiconductor package 100 with the mold compound 104 having been made transparent to provide a view inside the mold compound 104. As shown, structures like a semiconductor die 138 and passive components 140 are coupled to electrical contacts 142 on the substrate 102 (e.g., by solder joints). Furthermore, legs 144 and 146 of each metal member 106 are coupled to respective electrical contacts 142 on the substrate 102. These structures coupled to the substrate 102 are at least partially covered by the mold compound 104, as shown. The top segment 112 of each metal member 106 is large, providing ample contact area between the top segment 112 and the corresponding terminal 132, and yet the footprint of the semiconductor package 100 is not enlarged relative to the size that would be achieved without such a large top segment 112, at least in part because the top segment 112 overlaps with other components (e.g., the semiconductor die 138) in the top-down view.

In FIG. 1I, the mold compound 104 and the passive electrical component 130 are omitted to improve visibility of the substrate 102 and the various components coupled to the substrate 102. For example, the semiconductor die 138, the passive components 140, and the metal members 106

are visible. As shown, the top segment 112 includes a fourth side 148. The fourth side 148 is opposite and approximately parallel to the third side 118 and is approximately orthogonal to the first side 114 and the second side 116. The fourth side 148 may include one or more recessed portions 124, 126 and one or more non-recessed portions 120, 122. These recessed and non-recessed portions provide mechanical interlocking with the mold compound 104, as described above. In examples, the fourth side 148 is longer than the third side 118, and in other examples, the third side 118 is longer than the fourth side 148.

In examples, the legs 144, 146 are gullwing-style legs, although the scope of this description encompasses other shapes and styles of legs. The ends of the legs 144, 146 most distal to the top segment 112 are coupled (e.g., soldered) to respective electrical contacts 142 on the substrate 102. The electrical contacts 142 to which the legs 144, 146 are coupled are also coupled to the semiconductor die 138 and may be coupled to one or more other components within the semiconductor package 100.

Although each metal member 106 in the semiconductor package 100 includes two legs 144, 146, during the manufacturing stage and prior to singulation, each metal member 106 includes four legs and bridges two consecutive units of the substrate 102. The four legs of the pre-singulation metal member 106 provide adequate mechanical support to prevent toppling or tipping during the manufacturing stage. Stated another way, the four-legged metal member 106 provides enhanced mechanical stability during pick and place assembly operations by creating a wider, more stable structure with four or more legs that resists toppling and shifting during handling steps. The increased stability stems from the broader base of support that the bridge configuration provides compared to individual narrow connector elements. Such bridging across two adjacent units of the substrate 102 enables complex bridge clip geometries (e.g., two-legged clips) that would not be mechanically stable as standalone connectors. By coupling the bridge clip to adjacent units during assembly, the design may accommodate extended contact surfaces and protruding elements that provide improved electrical contact with inductor terminals. This approach allows for greater overlap between the connector and inductor terminals without requiring additional package footprint area, as the connector structure extends over the die area rather than consuming peripheral package space. Post-singulation, each metal member 106 in each semiconductor package 100 includes only two legs 144, 146, but having only two legs 144, 146 does not pose stability concerns in the finished and singulated semiconductor package 100 because the mold compound 104 has been applied. In this way, the improved design of the metal member 106 is realized, with a large top segment 112 and only two legs 144, 146 for support, resulting in no increase in package footprint area.

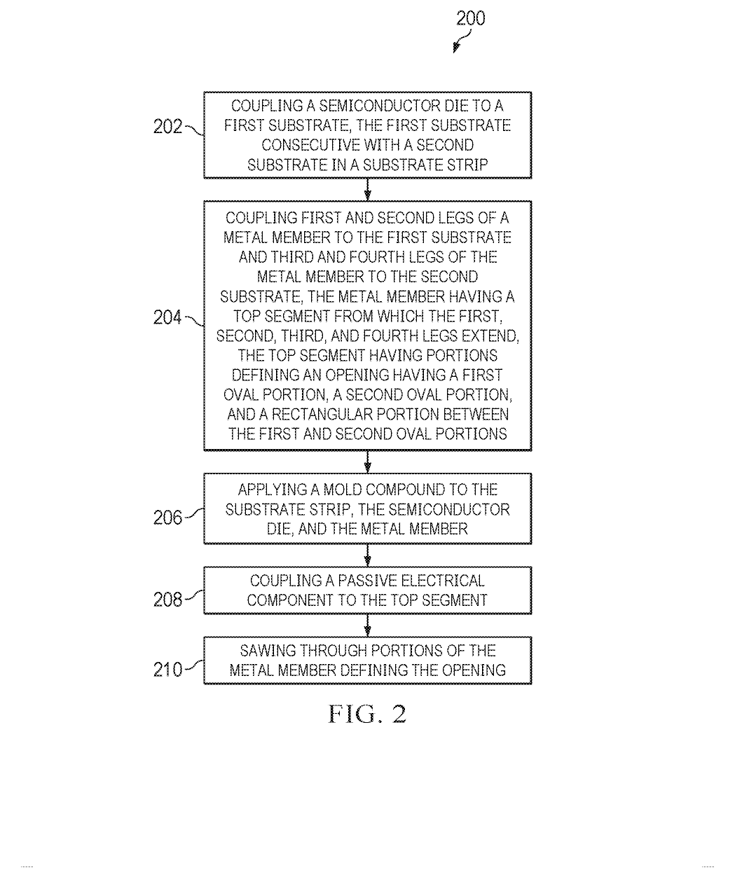

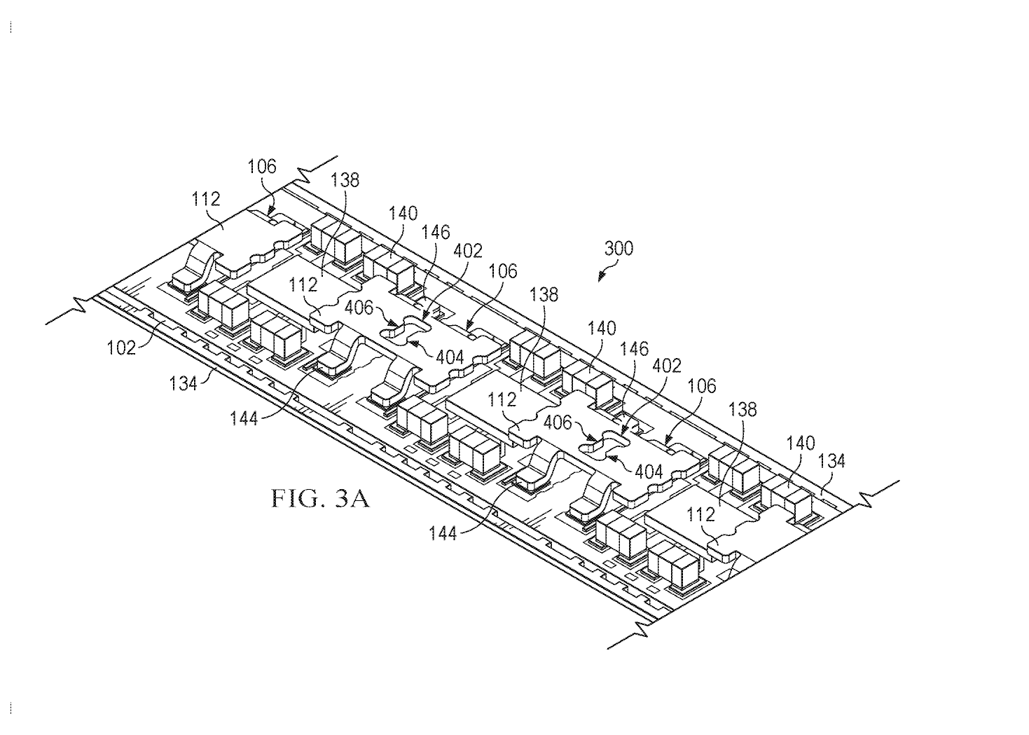

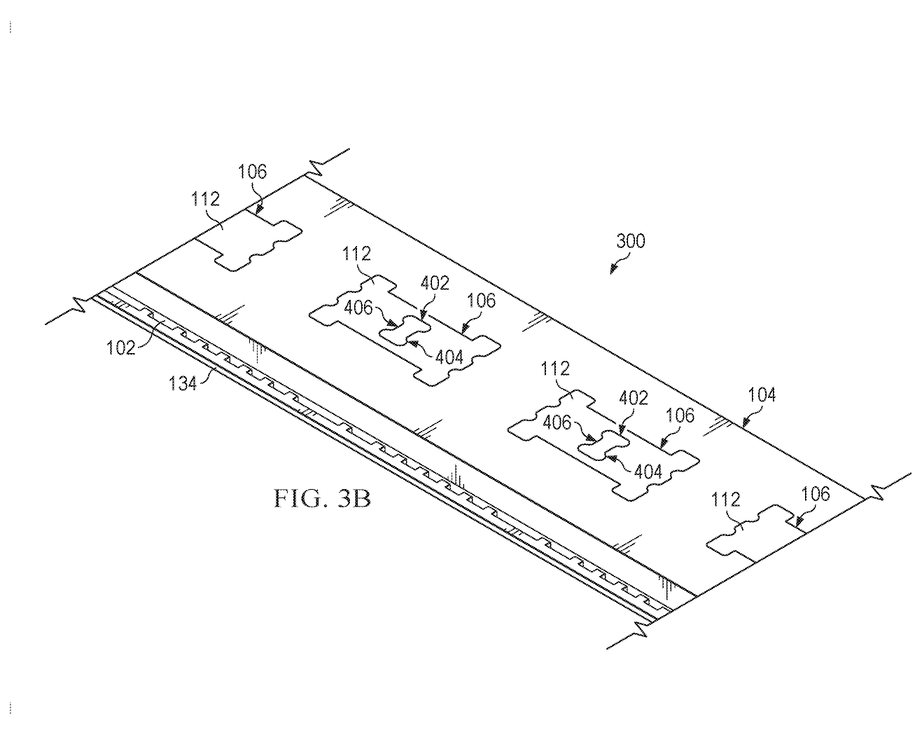

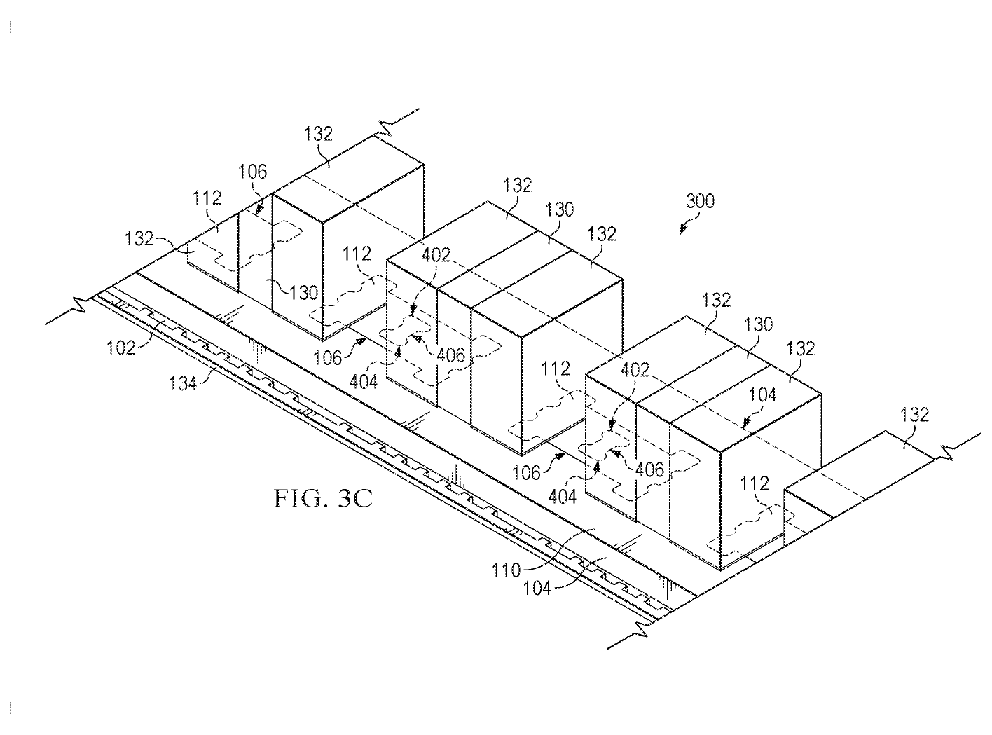

FIG. 2 is a flow diagram of a method 200 for manufacturing a semiconductor package 100 using metal members (e.g., bridge clips), in accordance with various examples. FIGS. 3A-3D are a process flow for manufacturing the semiconductor package 100 using metal members, in accordance with various examples. Accordingly, FIGS. 2 and 3A-3D are now described in parallel.

The method 200 for manufacturing a semiconductor package 100 using metal members 106 (e.g., bridge clips) includes step 202, which includes coupling a semiconductor die to a first substrate, where the first substrate is consecutive with a second substrate in a substrate strip. This substrate strip configuration allows for simultaneous processing of multiple semiconductor package units, thereby improving manufacturing throughput and efficiency. Step 204 includes coupling first and second legs of a metal member to the first substrate and third and fourth legs of the metal member to the second substrate. The metal member includes a top segment from which the first, second, third, and fourth legs extend. The top segment includes portions defining an opening having a first oval portion, a second oval portion, and a rectangular portion positioned between the first and second oval portions. This four-leg configuration provides enhanced mechanical stability during assembly operations by creating a broader base of support that resists toppling and shifting during handling steps. As shown in FIG. 3A, a substrate strip 300 includes multiple consecutive substrate units arranged in a linear configuration. Each substrate unit includes various electronic components (e.g., passive components 140) and semiconductor dies (e.g., semiconductor dies 138) coupled to a top surface of the substrate strip 300. The substrate strip 300 provides a continuous platform that facilitates automated assembly operations and enables each metal member 106 to span across adjacent units during the manufacturing process, with two legs 144, 146 coupled to a first unit of the substrate strip 300 and with two legs 144, 146 coupled to a second unit of the substrate strip 300 that is consecutive with the first unit. As shown in FIG. 3A, each metal member 106, and more specifically, the top segment 112 of each metal member 106, includes an opening having a dumbbell shape. In particular, the dumbbell-shaped opening includes oval portions 402 and 404 and a rectangular portion 406 between the oval portions 402 and 404. This opening provides multiple technical advantages. First, the opening reduces the amount of metal that will be cut by a mechanical saw during singulation, reducing manufacturing time and cost and increasing saw lifespan. Second, the opening provides the above-described recessed and non-recessed portions to facilitate mechanical interlocking with the mold compound 104. Third, the opening reduces the amount of stress provided to surrounding structures during mechanical sawing.

Step 206 of the method 200 includes applying a mold compound to the substrate strip, the semiconductor die, and the metal member. As illustrated in FIG. 3B, the mold compound 104 covers the entire substrate strip 300 and all mounted structures, forming a continuous molded assembly. The mold compound 104 encapsulates the semiconductor dies 138, the passive components 140, and portions of the metal members 106, while leaving specific areas exposed for subsequent component attachment in the manner described above. The mold compound 104 fills the recessed portions of the metal members 106, creating mechanical interlocking features that enhance adhesion and structural integrity.

Step 208 includes coupling a passive electrical component to the top segment of the metal member. FIG. 3C depicts this step, showing passive electrical components 130 coupled to the exposed portions (e.g., the top segments 112) of the metal members 106 through the top surface 110 of the mold compound 104. The passive electrical components 130 are coupled using solder joints that provide both mechanical attachment and electrical connectivity. The bridge clip design enables superior overlap between the inductor terminals and the metal member contact surfaces without requiring additional package footprint area.

Step 210 includes mechanically sawing through portions of the metal member defining the opening. More specifically, step 210 includes sawing through the dumbbell-shaped openings depicted in FIG. 3A. FIG. 3D shows the post-singulation semiconductor package 100 that is produced by mechanically sawing through the dumbbell-shaped openings in the metal members 106.

The bridge clip manufacturing approach provides several technical advantages during the assembly process. The four-leg configuration prevents component displacement during pick and place operations and reflow processes. The substrate strip format enables simultaneous processing of multiple units, reducing manufacturing cycle time and improving production efficiency. The dumbbell-shaped opening design allows for clean singulation with minimal saw blade wear and stress to surrounding structures while maintaining the structural integrity of the individual semiconductor packages after separation.

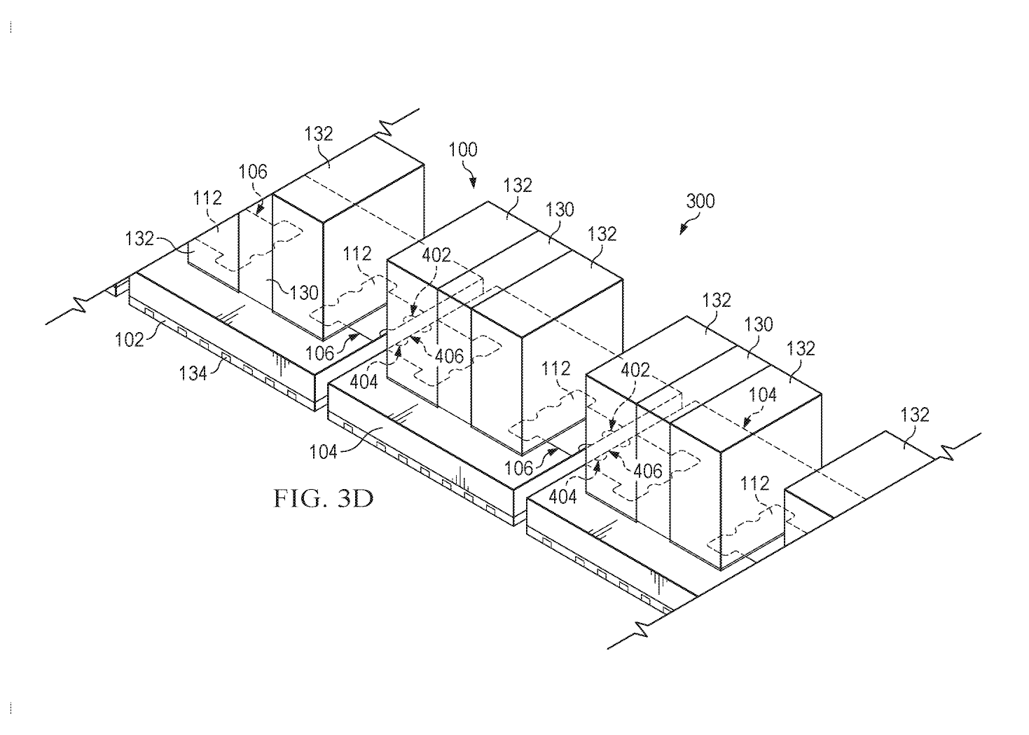

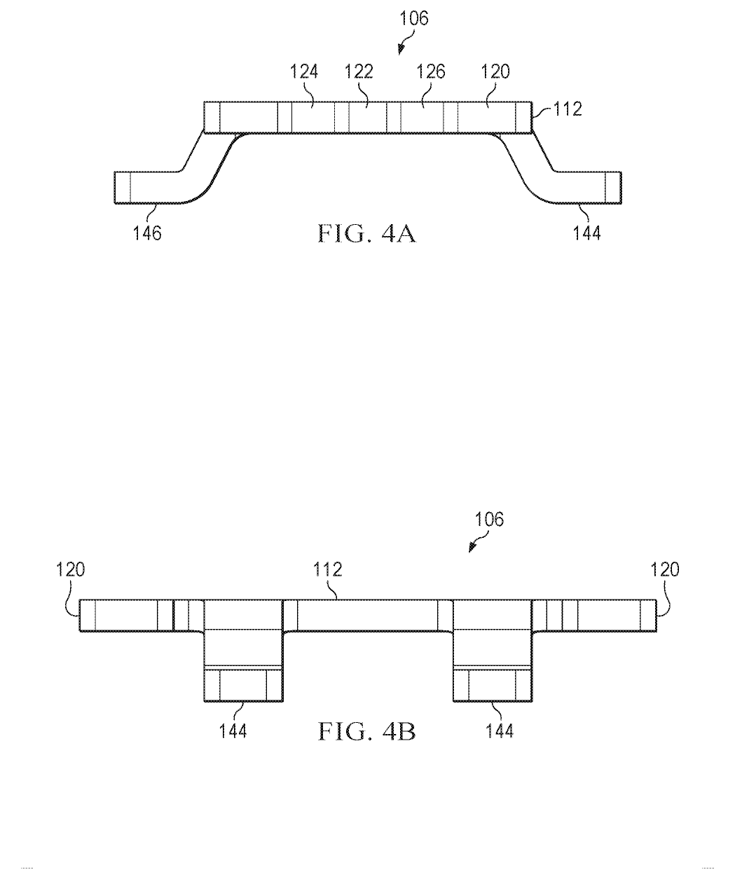

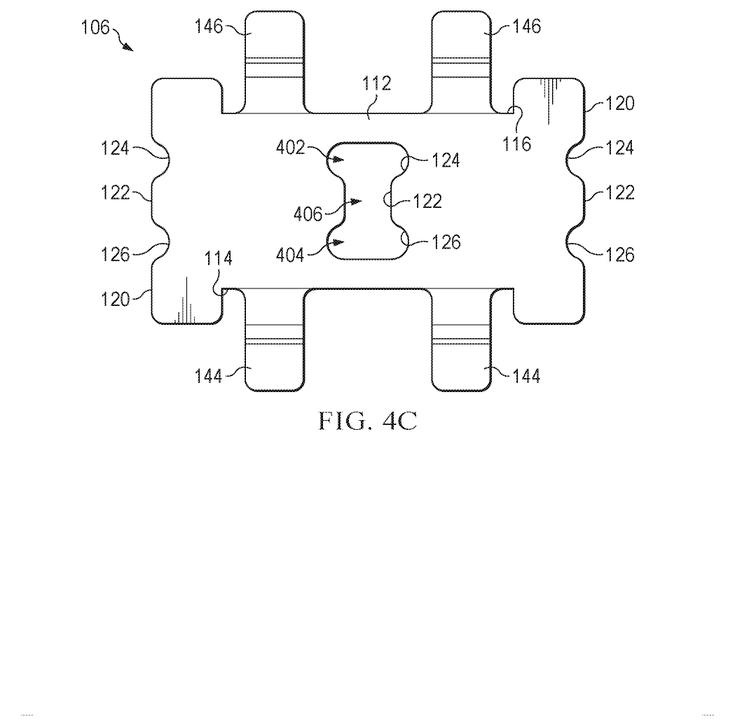

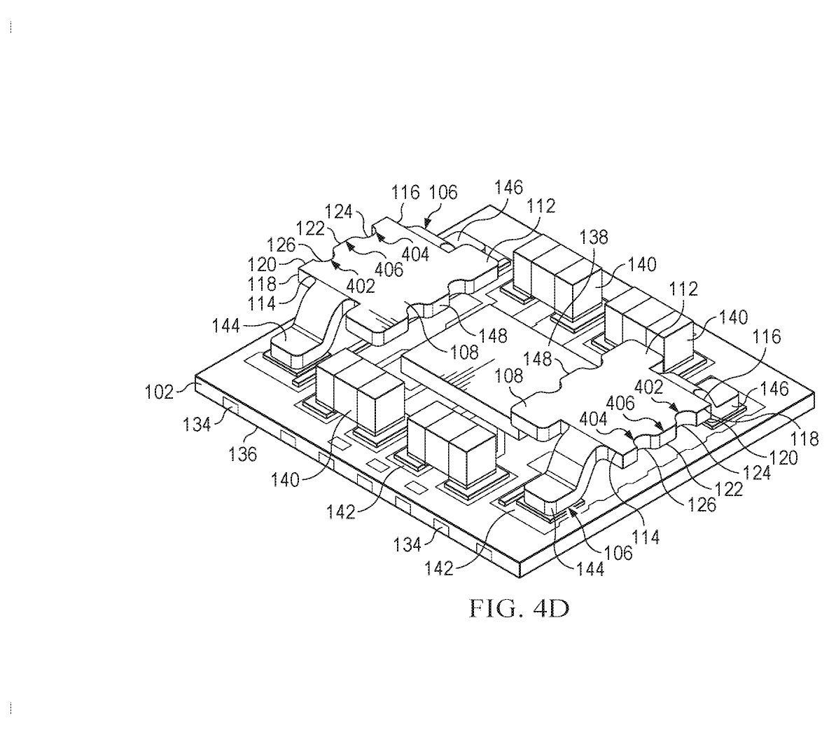

FIGS. 4A-4D show elevation, profile, top-down, and 3D views, respectively, of an example metal member 106. As shown, the example metal member 106 includes a top segment 112, a dumbbell-shaped opening in the top segment 112 defined by oval portions 402 and 404 and a rectangular portion 406 between the oval portions 402 and 404, and recessed portions 124, 126 and non-recessed portions 120, 122 on opposing ends of the top segment 112. The example metal member 106 further includes two legs 144 and two legs 146.

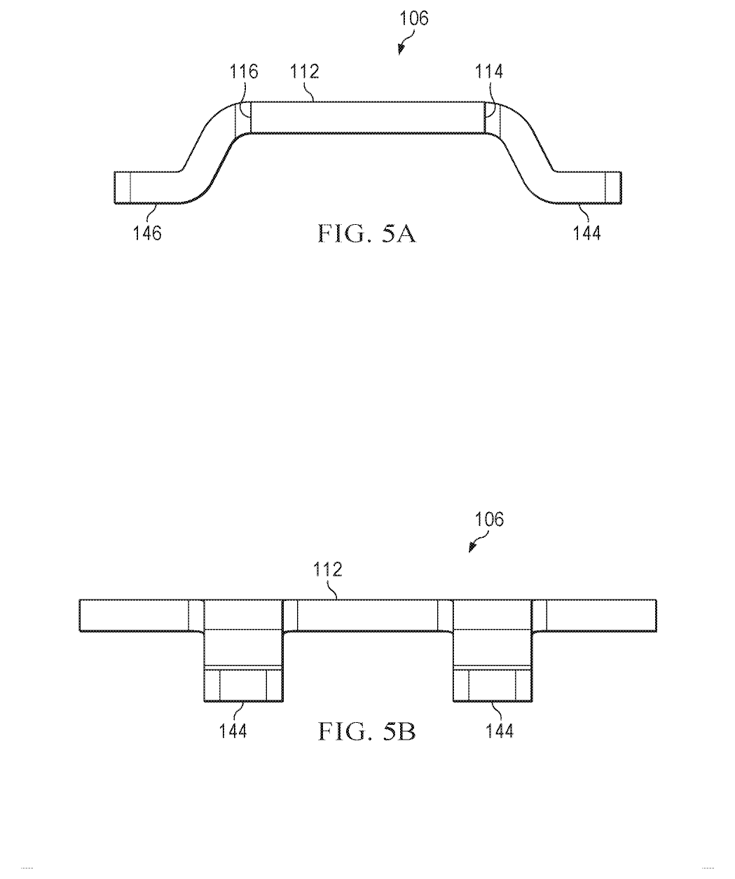

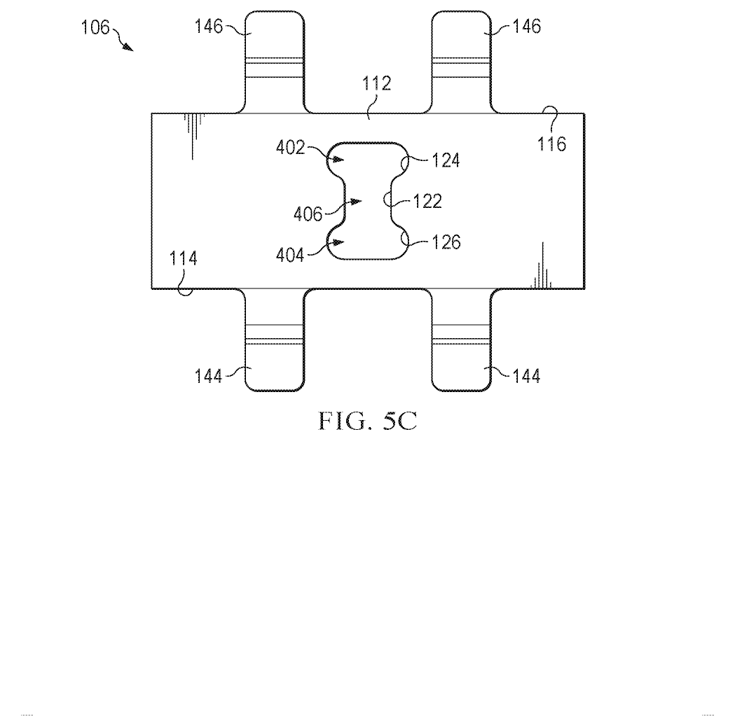

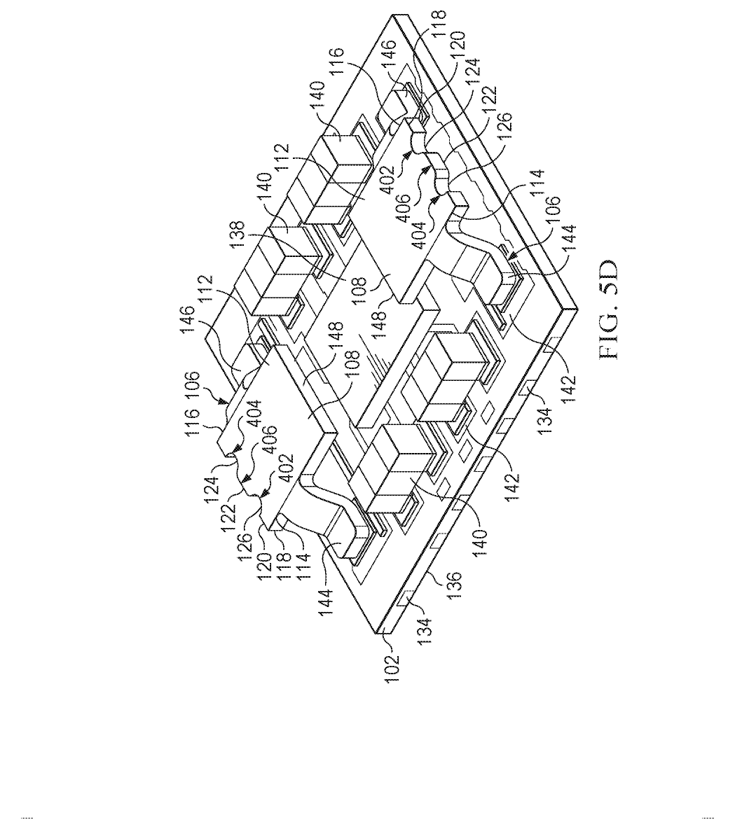

FIGS. 5A-5D show elevation, profile, top-down, and 3D views, respectively, of an example metal member 106. The example metal member 106 includes a top segment 112 having a dumbbell-shaped opening having oval portions 402 and 404 and a rectangular portion 406 between the oval portions 402 and 404. Two legs 144 and two legs 146 extend from the top segment 112, as shown.

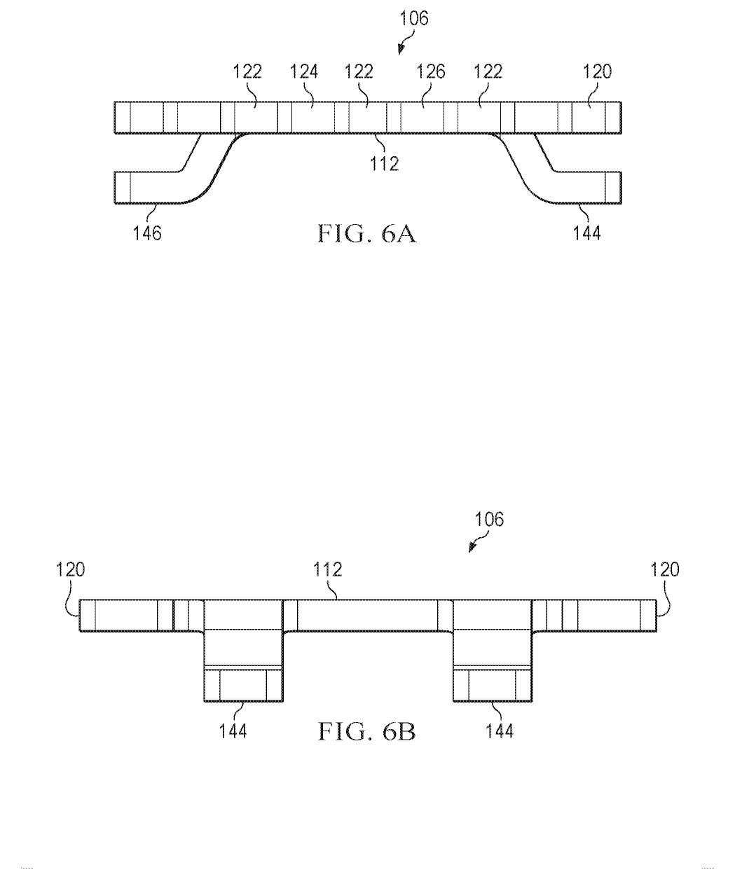

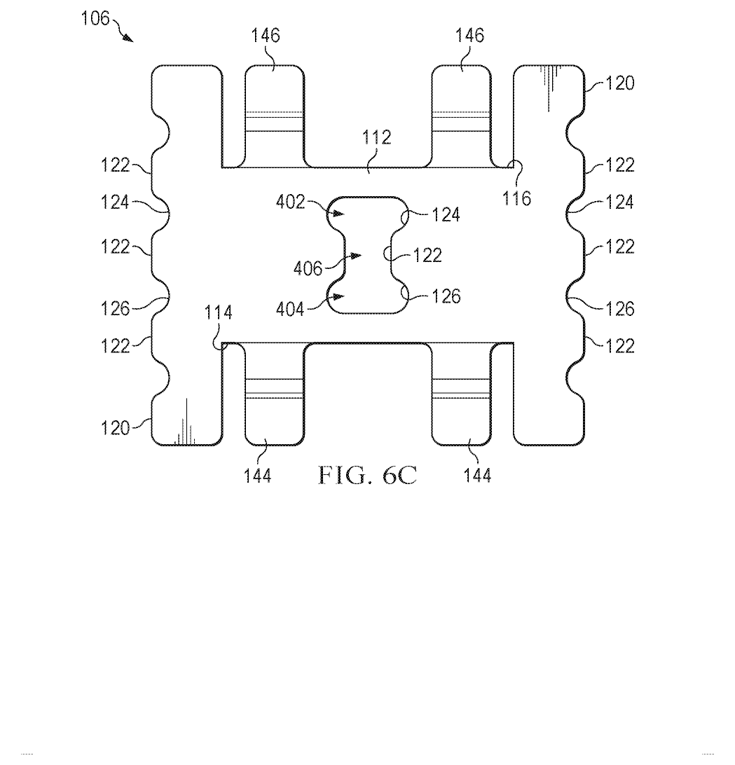

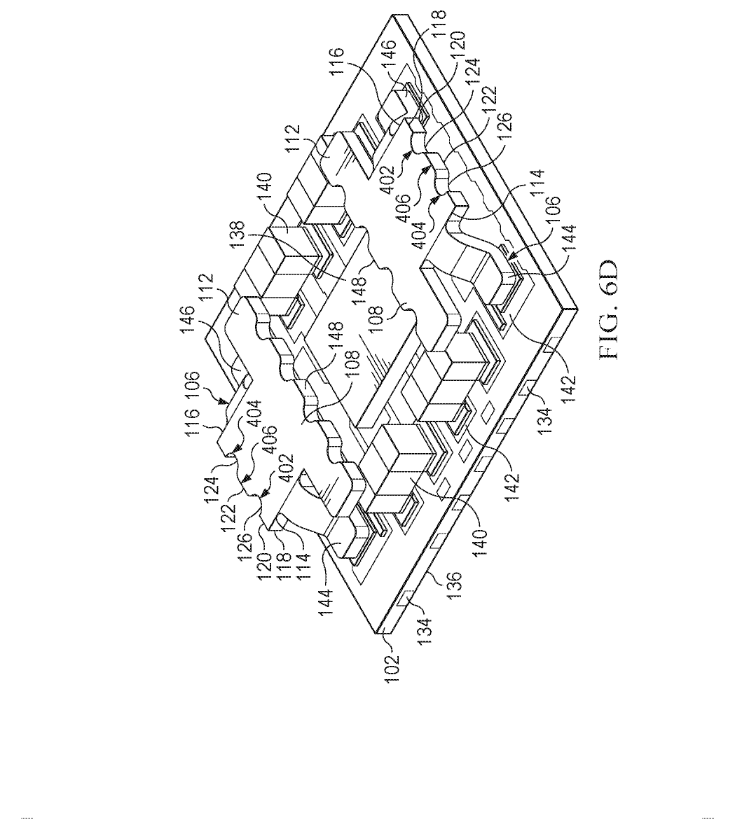

FIGS. 6A-6D show elevation, profile, top-down, and 3D views, respectively, of an example metal member 106. The example metal member 106 is identical to the metal member 106 of FIGS. 4A-4D, except that the opposing ends of the top segment 112 in which the recessed portions 124, 126 and non-recessed portions 120, 122 are located are larger than in FIGS. 4A-4D. Because these portions are larger, additional recessed portions and non-recessed portions may be included for enhanced mechanical interlocking with the mold compound 104.

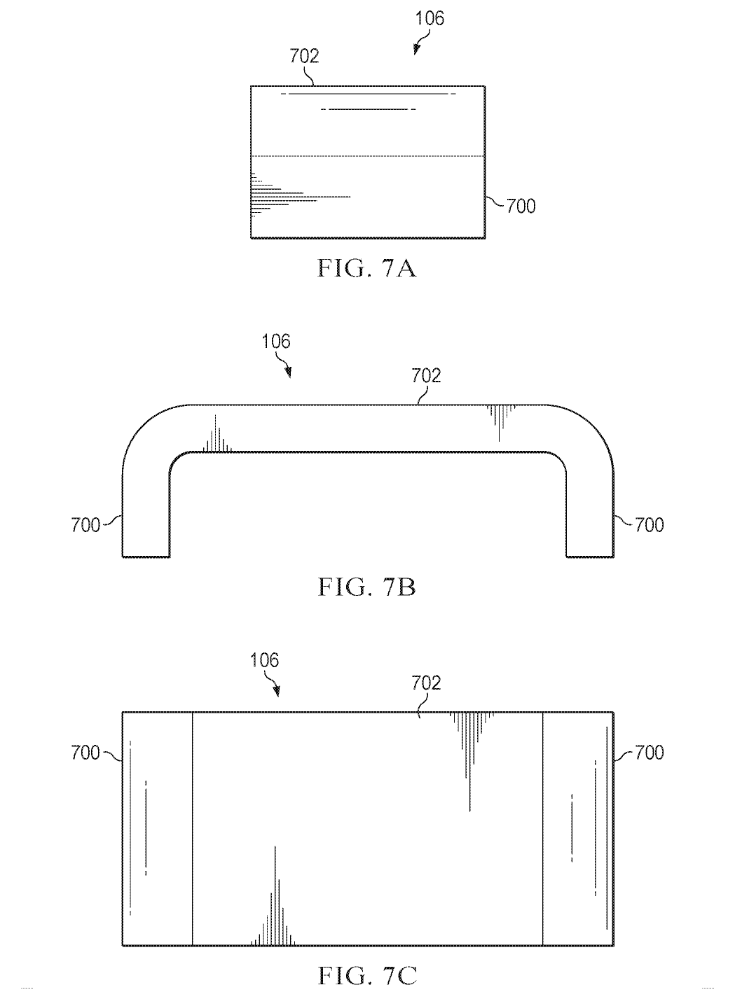

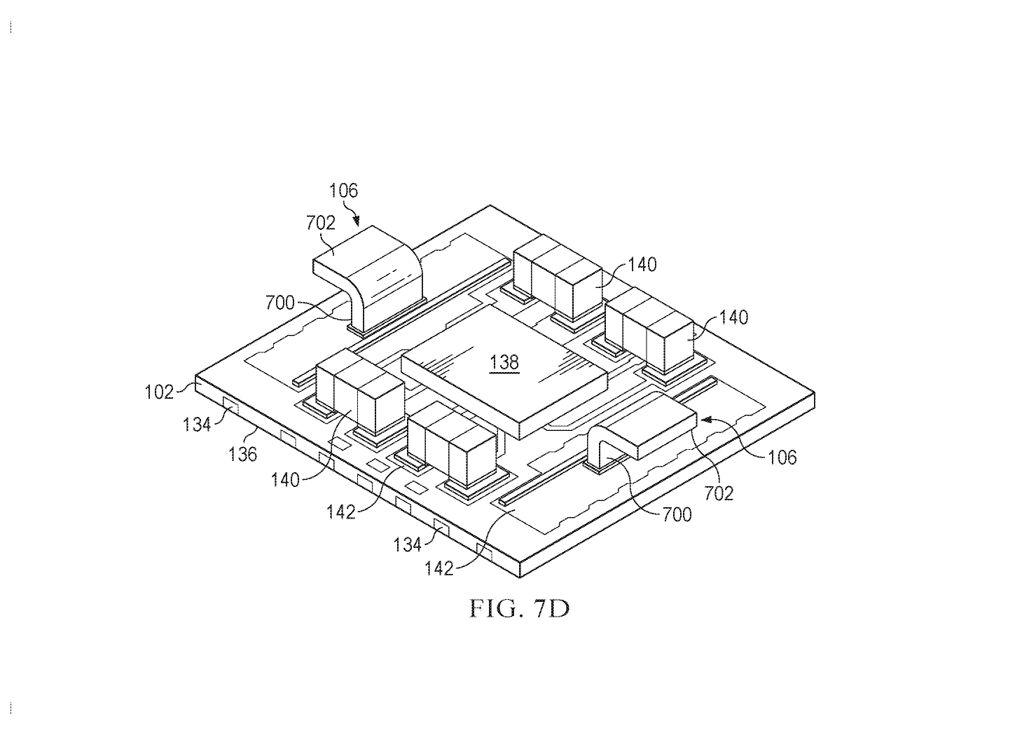

FIGS. 7A-7D are elevation, profile, top-down, and 3D views, respectively, of an example metal member 106. The example metal member 106 includes two vertical members 700 and a horizontal member 702 between the two vertical members 700. Transition segments between the horizontal member 702 and each of the two vertical members 700 may be curved, as shown. The example metal member 106 is coupled to consecutive substrate units in the substrate strip 300 during manufacture, as described above. The two vertical members 700 provide support during manufacture and prevent toppling or tipping of the metal member 106. After the mold compound 104 is applied, the horizontal member 702 is approximately bisected during singulation, with each resulting metal member 106 having only a single vertical member 700. However, because the mold compound 104 has been applied, no support is needed from the vertical members 700. A passive electrical component 130 may be coupled to the horizontal member 702 in the same manner as described above for the other example metal members 106.

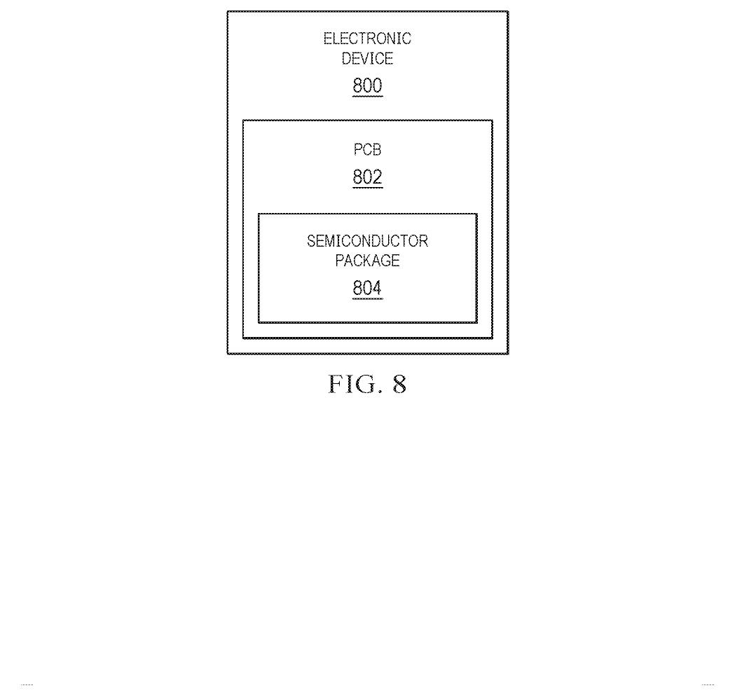

FIG. 8 is a block diagram of an electronic device 800 including a printed circuit board (PCB) 802 to which a semiconductor package 804 is coupled. The semiconductor package 804 includes a metal member 106, in accordance with various examples. The semiconductor package 804 is representative of the various examples of the semiconductor package 100 described herein. Examples of the electronic device 800 include a smartphone, a tablet, a laptop computer, a desktop computer, a television, a wireless audio device (e.g., headphones), a video game console, a wireless Internet device, a drone, a sensor, an aircraft, a space craft, a road vehicle, a home appliance, industrial equipment, a server, etc.

In this description, the term “couple” may include connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/- 10 percent of that parameter. Modifications are possible in the described examples, and other examples are possible within the scope of the claims.

As used herein, the terms “conductive terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a substrate having one or more electrical contacts;
a semiconductor die coupled to the substrate;
a metal member having a top segment and first and second legs, the first leg extending from a first side of the top segment to the one or more electrical contacts, the second leg extending from a second side of the top segment to the one or more electrical contacts;
a mold compound having top and bottom surfaces opposite each other, the bottom surface contacting the substrate, the top segment exposed through the top surface; and
a passive electrical component having an electrical contact coupled to the top segment.

2. The semiconductor package of claim 1, wherein a third side of the top segment includes a recessed portion and a non-recessed portion.

3. The semiconductor package of claim 2, wherein the mold compound includes a side surface orthogonal to the top surface of the mold compound, the non-recessed portion exposed through the side surface.

4. The semiconductor package of claim 2, wherein the mold compound fills a region defined by the recessed portion.

5. The semiconductor package of claim 2, wherein the third side includes a second non-recessed portion, the recessed portion in between the non-recessed portion and the second non-recessed portion, the recessed portion having a rounded wall.

6. The semiconductor package of claim 2, wherein a fourth side of the top segment opposes the third side, the fourth side is longer than the third side.

7. The semiconductor package of claim 6, wherein the fourth side includes a second recessed portion and a second non-recessed portion.

8. The semiconductor package of claim 7, wherein the mold compound fills a region defined by the second recessed portion.

9. The semiconductor package of claim 1, wherein the first and second legs extend in opposite directions in a top-down view.

10. The semiconductor package of claim 9, wherein the first and second legs have a gullwing shape.

11. A semiconductor package, comprising:
a substrate;
a semiconductor die coupled to the substrate;
a metal member having a top segment and first and second legs, the first and second legs extending in horizontally opposite directions and contacting the substrate, the top segment including first, second, third, and fourth sides, the first leg extending from the first side, the second leg extending from the second side, the third and fourth sides having straight and concave portions;
a mold compound contacting the substrate, the semiconductor die, and the metal member, a top surface of the top segment exposed through a top surface of the mold compound, the straight portions of the third side exposed through a side surface of the mold compound; and
a passive electrical component coupled to the top surface of the top segment.

12. The semiconductor package of claim 11, wherein the mold compound fills the concave portions of the third side.

13. The semiconductor package of claim 11, wherein the mold compound fills the concave portions of the fourth side.

14. The semiconductor package of claim 11, wherein the straight and concave portions are configured in an alternating manner.

15. The semiconductor package of claim 11, wherein the fourth side is longer than the third side, and wherein the third and fourth sides are orthogonal to the first and second sides.

16. The semiconductor package of claim 11, wherein the first and second legs have a gullwing shape.

17. A method for manufacturing a semiconductor package, comprising:
coupling a semiconductor die to a first substrate, the first substrate consecutive with a second substrate in a substrate strip;
coupling first and second legs of a metal member to the first substrate and third and fourth legs of the metal member to the second substrate, the metal member having a top segment from which the first, second, third, and fourth legs extend, the top segment having portions defining an opening having a first oval portion, a second oval portion, and a rectangular portion between the first and second oval portions;
applying a mold compound to the substrate strip, the semiconductor die, and the metal member;
coupling a passive electrical component to the top segment; and
sawing through the portions of the metal member defining the opening.

18. The method of claim 17, wherein the top segment includes two opposing sides, each of the two opposing sides having multiple concave portions and multiple straight portions.

19. The method of claim 18, wherein applying the mold compound includes covering the two opposing sides.

20. The method of claim 18, wherein a length of the top segment as measured through the opening is less than a length of the top segment along one of the two opposing sides.
